(19) United States
(12) Patent Application Publication
(10) Pub. No.: US 2025/0374416 A1
(43) Pub. Date: Dec. 4, 2025

(54) PCB CORE LAMINATE FOR WIRELESS POWER CHARGER AND METHOD OF MANUFACTURING THE SAME

(71) Applicants: Hyundai Motor Company, Seoul (KR); Kia Corporation, Seoul (KR); AMOSENSE CO.,LTD, Cheonan-si (KR)

(72) Inventors: Youngmin Kim, Hwaseong-si (KR); Jae-Jun Ko, Cheonan-si (KR); Chol Han Kim, Cheonan-si (KR); Kwangyeol Kim, Cheonan-si (KR)

(21) Appl. No.: 18/825,313

(22) Filed: Sep. 5, 2024

(30) Foreign Application Priority Data
May 29, 2024 (KR) 10-2024-0070393

(51) Int. Cl. H05K 1/02; H05K 1/03; H05K 1/09; H05K 3/46

(52) U.S. Cl. CPC H05K 1/0201; H05K 1/0306; H05K 1/0313; H05K 1/09; H05K 3/4626; H05K 2201/083

(57) ABSTRACT

An embodiment printed circuit board (PCB) core laminate for a wireless power charger includes a PCB substrate including a first PCB core and a second PCB core stacked on the first PCB core, wherein printed circuit patterns are located on surfaces of the PCB substrate, and a heat-dissipating material layer interposed between the first PCB core and the second PCB core.

### CROSS-REFERENCE TO RELATED APPLICATIONS

This application claims the benefit of Korean Patent Application No. 10-2024-0070393, filed on May 29, 2024, which application is hereby incorporated herein by reference.

### TECHNICAL FIELD

The present disclosure relates to a printed circuit board (PCB) core laminate for a wireless power charger and a method of manufacturing the same.

### BACKGROUND

Wireless charging systems use high frequencies of several tens of kHz to several MHz. Generally, a higher frequency increases power transmission capacity and efficiency but decreases a current-carrying cross-sectional area of a copper wire due to the skin effect, resulting in an increase in the resistance component.

In addition, as the resistance of a coil increases, a wireless power transmission system deteriorates in efficiency, resulting in an increase in conduction loss of the coil, which excessively increases the temperature of the coil, thereby causing a failure. To solve this problem that the resistance increases as the frequency increases, a Litz wire, which is made by twisting multiple thin strands of copper, is used.

A diameter of each strand of the Litz wire is selected according to a skin depth at an operating frequency, and the total number of strands is selected according to a current in the wire.

As the frequency increases, it is necessary to use a thinner copper wire, while an area occupied by a cross-sectional area of pure copper in an entire diameter of the Litz wire becomes smaller due to the shapes, insulations, and manufacturing tolerances of the copper wire strands, resulting in a problem that the diameter increases when compared to that of a single-strand wire having an equally current-carrying cross-sectional area.

In addition, the cost of the Litz wire increases significantly as the number of strands increases, and an occurrence of a problem that a strand is broken during a winding process decreases the number of valid strands and increases the conduction loss.

Furthermore, the coil using such a Litz wire commonly needs to be wound manually, whereby the inductance and the resistance of the coil are irregular, causing a problem that the productivity decreases.

A PCB-based coil has a limited current-carrying cross-sectional area when compared to that of the Litz coil, and thus, it is essential that a PCB be designed in such a manner that multiple layers are applied thereto.

The PCB coil is designed according to a design guide to which the following Equation 1 is applied.

$$I = k Δ {T}^{0.44} {A}^{0.725} \qquad Equation 1$$

In Equation 1, I represents a current (A), A represents a cross-sectional area (square mile, mi²), ΔT represents a temperature rise (C), and k represents a constant (0.048: outer layer, 0.024: inner layer).

According to Equation 1 above, an area of a copper layer required to carry the same current under constant temperature rise conditions varies depending on whether the copper layer is inside or outside the PCB.

For example, when ΔT is 20° C., the width of the 3 oz copper layer that is capable of carrying a current of 23 A is 4.967 mm when it is an outer layer and 12.92 mm when it is an inner layer.

Therefore, when the copper layer is formed as a layer outside the PCB, the copper layer is capable of carrying the same current with a track width of less than or equal to half that when the copper layer is formed as a layer inside the PCB.

In a case where it is intended to design a PCB core laminate with a multilayer structure having the same track width while applying the design of the PCB according to Equation 1 as described above, it is not possible to design a PCB core laminate with a multilayer structure having the same pattern width because inner and outer layers need to have different track widths in order to maintain the same current density.

### SUMMARY

By interposing a heat-dissipating material between PCB cores in a multilayer structure, embodiments of the present disclosure impart similar heat dissipation characteristics to a printed circuit pattern present on a surface between the PCB cores (hereinafter referred to as an “inner circuit layer”) and a printed circuit pattern present in contact with air on a surface outside the PCB cores (hereinafter referred to as an “outer circuit layer”).

Accordingly, embodiments of the present disclosure are capable of providing a PCB core laminate with a multilayer structure where an inner circuit layer and an outer circuit layer have the same track width.

An embodiment of the present disclosure provides a printed circuit board (PCB) core laminate for a wireless power charger that includes a PCB substrate and a first PCB core and a second PCB core including printed circuit patterns present on a surface of the PCB substrate, wherein the second PCB core is stacked on the first PCB core, and a heat-dissipating material layer is interposed between the first PCB core and the second PCB core.

The heat-dissipating material layer may include one or more types of resins among an ethylene-based resin, an acrylic-based resin, and an amide-based resin.

The heat-dissipating material layer may include one or more types of inorganic materials such as BN (boron nitride), Al₂O₃ (aluminum oxide), or both.

In the first PCB core or the second PCB core, the printed circuit patterns may be disposed on upper and lower surfaces of the PCB substrate.

In a cross-section of the PCB core laminate, the printed circuit pattern disposed on the upper surface of the PCB substrate and the printed circuit pattern disposed on the lower surface of the PCB substrate may be arranged to correspond to each other.

In a cross-section of the PCB core laminate, a difference in pattern width between the printed circuit pattern disposed on the upper surface of the PCB substrate and the printed circuit pattern disposed on the lower surface of the PCB substrate may be smaller than or equal to 5%.

A cut-out portion penetrating a portion of the PCB substrate may be present in the first PCB core or the second PCB core.

The cut-out portion may be present through a central portion of the PCB substrate in the first PCB core or the second PCB core.

The cut-out portion may be filled with a heat-dissipating material.

In a cross-section of the PCB core laminate, heat-conducting frames may be connected to side end portions of the heat-dissipating material layer.

One or more layers of PCB cores may be stacked on the second PCB core, and a heat-dissipating material layer is interposed between the PCB cores.

A magnetic sheet and a control PCB may be stacked on the second PCB core.

A heat-dissipating material layer may be interposed between the second PCB core and the magnetic sheet, and a heat-dissipating material layer may be interposed between the magnetic sheet and the control PCB.

The PCB core laminate according to an embodiment is capable of, by interposing a heat-dissipating material between PCB cores in a multilayer structure, imparting similar heat dissipation characteristics to a printed circuit pattern present on a surface between the PCB cores (hereinafter referred to as an “inner circuit layer”) and a printed circuit pattern present in contact with air on a surface outside the PCB cores (hereinafter referred to as an “outer circuit layer”).

In addition, the PCB core laminate according to an embodiment can be designed to have a multilayer structure where an inner circuit layer and an outer circuit layer have the same track width.

### BRIEF DESCRIPTION OF THE DRAWINGS

FIG. 1 is a diagram schematically illustrating a cross-section of a PCB core laminate in an embodiment.

FIGS. 2 to 7 are diagrams each schematically illustrating a cross-section of a PCB core laminate in another embodiment.

### DETAILED DESCRIPTION OF ILLUSTRATIVE EMBODIMENTS

The advantages and features of the technology and the methods for accomplishing the same will be apparent from the exemplary embodiments to be described below. However, modes for carrying out the present disclosure are not limited to the exemplary embodiments set forth herein. Unless otherwise defined, all terms (including technical and scientific terms) used herein have meanings commonly understood by those having ordinary skill in the art. In addition, terms defined in commonly used dictionaries are not to be ideally or exaggeratedly interpreted unless explicitly defined otherwise.

Throughout the specification, unless explicitly described to the contrary, the words “comprise/include,” and variations such as “comprises/includes” or “comprising/including,” will be understood to imply the inclusion of stated elements but not the exclusion of any other elements. Further, singular forms includes plural forms unless mentioned otherwise.

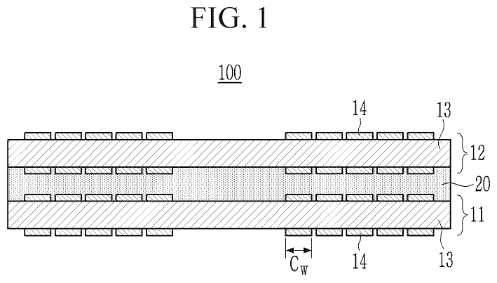

FIG. 1 schematically illustrates a cross-section of a PCB core laminate 100 according to an embodiment. As shown in FIG. 1, the PCB core laminate 100 for a wireless power charger includes a printed circuit board (PCB) substrate 13 and a first PCB core 11 and a second PCB core 12 including printed circuit patterns 14 present on surfaces of the PCB substrate 13. The second PCB core 12 is stacked on the first PCB core 11 with a heat-dissipating material layer 20 interposed between the first PCB core 11 and the second PCB core 12. The structure of the PCB core laminate 100 in FIG. 1 merely exemplifies an embodiment of the present disclosure, and the present disclosure is not limited thereto. Therefore, various modifications may be made, for example, by adding other configurations to the configuration of the PCB core laminate 100 shown in FIG. 1.

As shown in FIG. 1, while the printed circuit pattern 14 present on a lower surface of the first PCB core 11 and the printed circuit pattern 14 present on an upper surface of the second PCB core 12 are easy to dissipate heat from because they are present in contact with air on an external surface of the PCB core laminate 100, the printed circuit pattern 14 present on an upper surface of the first PCB core 11 and the printed circuit pattern 14 present on a lower surface of the second PCB core 12 are difficult to dissipate heat from because they are present on an internal surface of the PCB core laminate 100. Due to this difference in the heat dissipation characteristic, it is inevitable to give a difference in track width between the printed circuit patterns 14 in order to maintain the same current density.

According to one embodiment, by interposing the heat-dissipating material layer 20 between the first PCB core 11 and the second PCB core 12, the same level of heat dissipation characteristic can be imparted to the internal printed circuit patterns 14 as the external printed circuit patterns 14, thereby minimizing the difference in track width between the internal printed circuit patterns 14 and the external printed circuit patterns 14.

The heat-dissipating material layer 20 may include one or more types of resins among an ethylene-based resin, an acrylic-based resin, and an amide-based resin. More specifically, the heat-dissipating material layer 20 may include polypropylene (PP) or polyamide 6 (PA6).

The heat-dissipating material layer 20 may include one or more types of inorganic materials such as BN or Al₂O₃. In other words, the heat-dissipating material layer comprises one or more types of inorganic materials that include BN or Al₂O₃, i.e., BN, Al₂O₃, or both BN and Al₂O₃, with or without other materials. These inorganic materials have excellent thermal conductivity and impart heat dissipation performance to the heat-dissipating material layer 20.

According to an embodiment, the heat dissipation characteristic of the heat-dissipating material layer 20 can be appropriately controlled by appropriately controlling a ratio between the resin and the inorganic material in the heat-dissipating material layer 20.

The printed circuit pattern 14 may include a conductive material, more particularly copper. Although not illustrated in FIG. 1, etc., the conductive material may be wound in multiple turns from the outside to the inside on the surface of the PCB substrate 13 to form a spiral track. Since the material and the pattern shape of the printed circuit pattern 14 are widely known, the detailed description thereof is omitted.

As shown in FIG. 1, the printed circuit patterns 14 may be arranged on both upper and lower surfaces of the PCB substrate 13.

In addition, in a cross-section of the PCB core laminate 100, the printed circuit pattern disposed on the upper surface of the PCB substrate and the printed circuit pattern disposed on the lower surface of the PCB substrate may be arranged to correspond to each other. In addition, the printed circuit patterns 14 disposed on the first PCB core 11 and the printed circuit patterns 14 disposed on the second PCB core 12 may be arranged to correspond to each other. The corresponding arrangement means that the printed circuit patterns 14 are present in parallel to each other at the same location in the thickness direction of the PCB core laminate 100.

As shown in FIG. 1, while the printed circuit pattern 14 present on a lower surface of the first PCB core 11 and the printed circuit pattern 14 present on an upper surface of the second PCB core 12 are easy to dissipate heat from because they are present in contact with air on a surface outside the PCB core laminate, the printed circuit pattern 14 present on an upper surface of the first PCB core 11 and the printed circuit pattern 14 present on a lower surface of the second PCB core 12 are difficult to dissipate heat from because they are present on a surface inside the PCB core laminate. Due to this difference in the heat dissipation characteristic, it is inevitable to give a difference in track width between the printed circuit patterns 14 in order to maintain the same current density.

According to an embodiment, by interposing the heat-dissipating material layer 20 between the first PCB core 11 and the second PCB core 12, the same level of heat dissipation characteristic can be imparted to the internal printed circuit patterns 14 as the external printed circuit patterns 14, thereby minimizing the difference in track width between the internal printed circuit patterns 14 and the external printed circuit patterns 14. More specifically, the difference in pattern width C_{W} between the printed circuit pattern disposed on the upper surface of the PCB substrate and the printed circuit pattern 14 disposed on the lower surface of the PCB substrate may be smaller than or equal to 5%. The pattern width C_{W} of the printed circuit pattern 14 may be obtained by [difference in width between printed circuit patterns]/[average of widths of printed circuit patterns] at corresponding locations. More specifically, the difference in pattern width C_{W} may be smaller than or equal to 1%.

The PCB substrate 13 is a printed circuit board and refers to a board on which various electronic components such as IC chips, resistors, coils, and capacitors are connected to a plastic plate with copper wiring printed thereon.

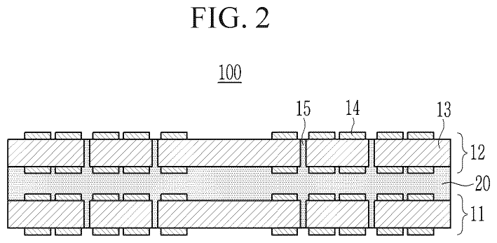

As shown in FIG. 2, a cut-out portion 15 penetrating a portion of the PCB substrate 13 may be present in the first PCB core 11 or the second PCB core 12. The cut-out portion 15 may be present at a location of the PCB substrate 13 where the printed circuit pattern 14 is not disposed. Since the cut-out portion 15 is present in the PCB substrate 13, the heat dissipation characteristic can be further improved.

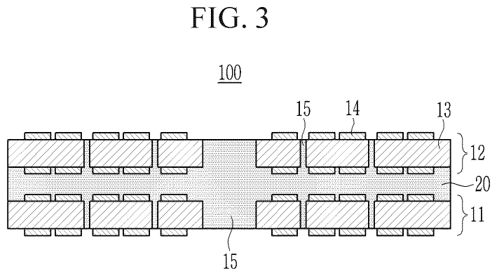

In addition, as illustrated in FIG. 3, a cut-out portion 15 may be present in a central portion of the PCB substrate 13. The central portion refers to a location from the center of the PCB substrate 13 to the printed circuit patterns 14 that are located closest to the center of the PCB substrate 13 in the cross-section of the PCB core laminate 100.

As shown in FIGS. 2 and 3, the cut-out portions 15 may be filled with a heat-dissipating material. The filled heat-dissipating material may be the same as the material of the heat-dissipating material layer 20, and the description thereof is omitted.

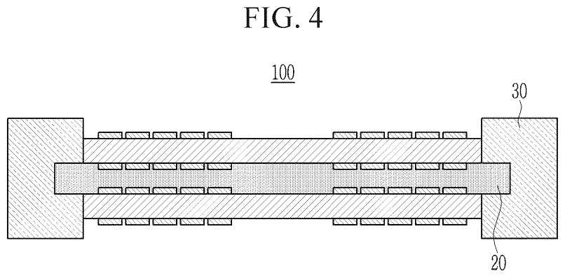

As shown in FIG. 4, in the cross-section of the PCB core laminate 100, heat-conducting frames 30 may be connected to side end portions of the heat-dissipating material layer 20. This can further improve the heat dissipation characteristic. The heat dissipation characteristic can be further improved by adding a water-cooling or air-cooling element to the heat conducting frames 30. Specifically, the side end portions of the heat-dissipating material layer 20 may be embedded between the heat-conducting frames 30.

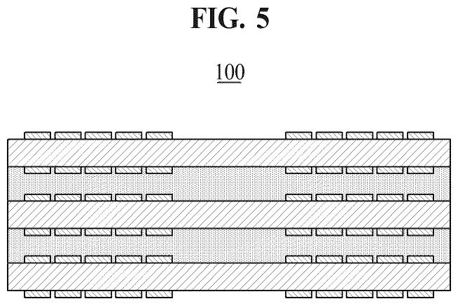

Although it is shown in FIG. 1 as an example that the PCB cores are stacked in two layers, the PCB cores may be stacked in three or more layers. In this case, by interposing the heat-dissipating material layer 20 between the PCB cores, the heat dissipation characteristic of the internal circuit layer can be adjusted to be similar to the heat dissipation characteristic of the external circuit layer. For example, in FIG. 5, one or more layers of PCB cores may be additionally stacked on the second PCB core 12, and a heat-dissipating material layer 20 may be interposed between the PCB cores.

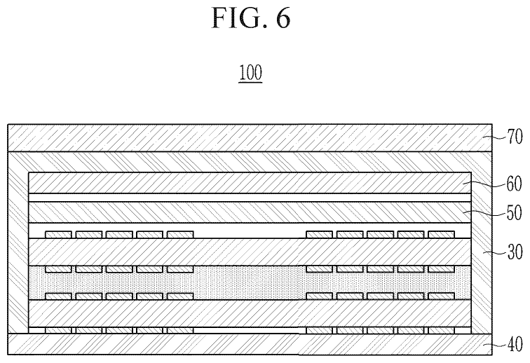

In addition, additional layers may be stacked on the second PCB core 12 if necessary. As shown in FIG. 6, a magnetic sheet 50 and a control PCB 60 may be stacked on the second PCB core 12. As the magnetic sheet 50, an amorphous sheet or a ferrite sheet made of an amorphous ribbon having a high magnetic permeability may be used. Any amorphous sheet having a high magnetic permeability may be used. For example, an amorphous ribbon in the form of a thin plate made of an Fe-based, Co-based, or Ni-based amorphous alloy may be used. Alternatively, for the magnetic sheet 50, permalloy having excellent soft magnetic properties, molypermalloy powder (MPP) containing molybdenum (Mo), or the like may be applied.

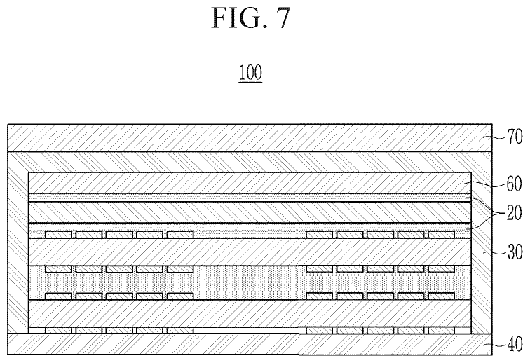

In addition, as shown in FIG. 7, a heat-dissipating material layer 20 may be interposed between the second PCB core 12 and the magnetic sheet 50, and a heat-dissipating material layer 20 may be interposed between the magnetic sheet 50 and the control PCB 60. This can further improve the heat dissipation characteristic of the PCB core laminate 100.

As shown in FIGS. 6 and 7, the PCB core laminate 100 may further include a heat-conducting frame 30, a lower cover 40 disposed under the first PCB core 11, and a cooling module 70 connected to the heat-conducting frame 30.

A PCB core laminate for a wireless power charger according to an embodiment may be manufactured by stacking the first PCB core 11 and the second PCB core 12 with the heat-dissipating material layer 20 interposed therebetween, and then pressing them. By applying an appropriate pressure to press them, the heat-dissipating material layer 20 may be interposed between the first PCB core 11 and the second PCB core 12 with a minimal empty space.

The PCB core laminate 100 according to an embodiment may be usefully used for a wireless power charger. More specifically, the PCB core laminate 100 according to an embodiment may be usefully used for the purpose of charging a battery that supplies electrical energy to a motor for driving an electric vehicle.

Specific examples of embodiments of the disclosure will be presented below. However, the examples described below are only intended to specifically exemplify or explain embodiments of the disclosure, and the scope of the disclosure should not be limited thereby.

### Heat Dissipation Characteristic

The PCB core laminate 100 illustrated in FIG. 6 was manufactured. The lower cover 40 was made of polycarbonate (thermal conductivity: 0.2 W/m K), the PCB substrates 13 and 60 were made of FR4 (thermal conductivity: 0.35 W/m K), the printed circuit pattern 14 was made of Cu (thermal conductivity: 387.6 W/m K), the magnetic sheet 50 was made of a ferrite sheet (plane: 2.057 and through: 4.665), the heat-conducting frame 30 was made of Al die-cast (thermal conductivity: 100 W/m K), and the cooling module 70 was made of Al die-cast (thermal conductivity: 100 W/m K).

In an example, a heat-dissipating material layer 20 having a thermal conductivity of 1 W/m K was interposed between a first PCB core 11 and a second PCB core 12.

In a comparative example, a first PCB core 11 and a second PCB core 12 were placed with an empty space therebetween without a heat-dissipating material layer 20.

After operating the PCB core laminate 100, its temperature was measured. The temperature was 92.7° C. in the example, while the temperature was 366.4° C. in the comparative example, confirming that an excellent heat dissipation characteristic was obtained by interposing the heat-dissipating material layer 20.

Although the preferred exemplary embodiments of the present disclosure have been described in detail above, the scope of the present disclosure is not limited thereto, and various modifications and improvements made by those skilled in the art using the basic concepts of embodiments of the present disclosure defined in the following claims also fall within the scope of the present disclosure.

The following reference identifiers may be used in connection with the figures to describe various features of embodiments of the present disclosure.

| | |
|---|---|
| 100: PCB core laminate | 11: first PCB core |
| 12: second PCB core | 13: PCB substrate |
| 14: printed circuit pattern | 15: cut-out portion |
| 20: heat-dissipating material layer | 30: heat-conducting frame |
| 40: lower cover | 50: magnetic sheet |
| 60: control PCB | 70: cooling module |

What is claimed is:

1. A printed circuit board (PCB) core laminate for a wireless power charger, the PCB core laminate comprising:
a PCB substrate comprising a first PCB core and a second PCB core stacked on the first PCB core, wherein printed circuit patterns are located on surfaces of the PCB substrate; and
a heat-dissipating material layer interposed between the first PCB core and the second PCB core.

2. The PCB core laminate of claim 1, wherein the heat-dissipating material layer comprises one or more types of resins among an ethylene-based resin, an acrylic-based resin, and an amide-based resin.

3. The PCB core laminate of claim 2, wherein the heat-dissipating material layer comprises one or more types of inorganic materials that include BN or Al₂O₃.

4. The PCB core laminate of claim 1, wherein, in the first PCB core or the second PCB core, the printed circuit patterns are disposed on upper and lower surfaces of the PCB substrate.

5. The PCB core laminate of claim 4, wherein, in a cross-section of the PCB core laminate, the printed circuit pattern disposed on the upper surface of the PCB substrate and the printed circuit pattern disposed on the lower surface of the PCB substrate are arranged to correspond to each other.

6. The PCB core laminate of claim 4, wherein, in a cross-section of the PCB core laminate, a difference in pattern width between the printed circuit pattern disposed on the upper surface of the PCB substrate and the printed circuit pattern disposed on the lower surface of the PCB substrate is smaller than or equal to 5%.

7. The PCB core laminate of claim 1, further comprising a cut-out portion penetrating a portion of the PCB substrate in the first PCB core or the second PCB core.

8. The PCB core laminate of claim 7, wherein the cut-out portion is present through a central portion of the PCB substrate in the first PCB core or the second PCB core.

9. The PCB core laminate of claim 8, wherein the cut-out portion is filled with a heat-dissipating material.

10. The PCB core laminate of claim 7, wherein the cut-out portion is filled with a heat-dissipating material.

11. The PCB core laminate of claim 1, wherein, in a cross-section of the PCB core laminate, heat-conducting frames are connected to side end portions of the heat-dissipating material layer.

12. The PCB core laminate of claim 1, wherein one or more layers of PCB cores are stacked on the second PCB core, and the heat-dissipating material layer is interposed between the PCB cores.

13. The PCB core laminate of claim 1, further comprising a magnetic sheet and a control PCB stacked on the second PCB core.

14. The PCB core laminate of claim 13, further comprising:
a second heat-dissipating material layer interposed between the second PCB core and the magnetic sheet; and
a third heat-dissipating material layer interposed between the magnetic sheet and the control PCB.

15. A method of manufacturing a printed circuit board (PCB) core laminate for a wireless power charger, the method comprising:
stacking a first PCB core and a second PCB core with a heat-dissipating material layer interposed between the first PCB core and the second PCB core, wherein printed circuit patterns are located on surfaces of the first PCB core and the second PCB core; and
pressing the first PCB core and the second PCB core together.

16. The method of claim 15, wherein the heat-dissipating material layer comprises one or more types of resins among an ethylene-based resin, an acrylic-based resin, and an amide-based resin.

17. The method of claim 15, wherein, in a cross-section of the PCB core laminate, the printed circuit patterns disposed on the first PCB core and the printed circuit patterns disposed on the second PCB core are arranged to correspond to each other.

18. The method of claim 15, further comprising connecting heat-conducting frames to side end portions of the heat-dissipating material layer.

19. The method of claim 15, further comprising stacking a magnetic sheet and a control PCB on the second PCB core.

20. The method of claim 19, further comprising:
interposing a second heat-dissipating material layer between the second PCB core and the magnetic sheet; and
interposing a third heat-dissipating material layer between the magnetic sheet and the control PCB.
